(19) United States
(12) Patent Application Publication
(10) Pub. No.: US 2016/0133553 A1
(43) Pub. Date: May 12, 2016

(54) PRINTED CIRCUIT BOARD AND MANUFACTURING METHOD THEREOF

(71) Applicant: Samsung Electro-Mechanics Co., Ltd., Suwon-si (KR)

(72) Inventor: Sung Yeol PARK, Suwon-si (KR)

(73) Assignee: Samsung Electro-Mechanics Co., Ltd., Suwon-si (KR)

(21) Appl. No.: 14/936,053

(22) Filed: Nov. 9, 2015

(30) Foreign Application Priority Data
Nov. 10, 2014 (KR) 10-2014-0155265

(51) Int. Cl. H01L 23/498; H05K 3/22; H01L 21/768; H05K 3/06

(52) U.S. Cl. CPC H01L 23/49816; H05K 3/06; H05K 3/22; H01L 23/49838; H01L 21/76877; H01L 23/49866

(57) ABSTRACT

A printed circuit board includes: an insulation layer including circuit patterns, the circuit patterns having a groove formed therein; a metal protection layer (disposed in the groove; a solder resist layer disposed on the insulation layer and having an opening exposing the circuit patterns; and a solder bump disposed on the opening.

### CROSS-REFERENCE TO RELATED APPLICATION(S)

This application claims the benefit of Korean Patent Application No. 10-2014-0155265, filed on Nov. 10, 2014 in the Korean Intellectual Property Office, the entire disclosure of which is incorporated herein by reference for all purposes.

### BACKGROUND

1. Field

The following description relates to a printed circuit board and a manufacturing method thereof.

2. Description of Related Art

In general, there are three types of methods for connecting a chip on a substrate: a wire bonding method; a tape automated bonding (TAB) method; and a flip chip connection method. In the tape automated bonding (TAB) method and the flip chip connection method, solder bumps are formed to electrically connect the chip to the substrate.

Generally, conductive pads such as a high-performance substrate, an integrated circuit (IC) chip, and the like, include a metal protection layer (under bump metallurgy (UBM)). The UBM is a portion of a metal pad for connecting electrical circuits in the substrate or the chip to external components.

In general, in the case in which solder wire soldering used for mounting a passive component, reflow soldering that uses a solder cream, wave soldering that uses a molten solder, and the like, are used, at the time of manufacturing a substrate, a protection layer of a metal film made of nickel (Ni)/tin (Sn)/gold (Au), or the like, is formed on circuit patterns by a plating method. Then, a solder is applied on the protection layer. However, in the case of active components such as such as ICs and the like, or high-density mounting substrates, a packing process is performed in such a manner that a separate solder ball is formed so that the solder does not directly contact the substrate or the chip. Here, formation of the solder ball is referred as bumping, and the solder ball is formed on the UBM.

That is, in order to safely install and fuse the solder ball, the UBM made of chromium (Cr) nickel (Ni), gold (Au), or the like, is formed on the conductive pad made of aluminum (Al) or copper (Cu) formed on the chip or the substrate by a thin film method or a plating method. Then, a soldering process is performed on the UBM.

Korean Patent Laid-Open Publication No. 2005-0020236 discloses a method of forming a solder bump.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

According to one general aspect, a printed circuit board includes: an insulation layer including circuit patterns, the circuit patterns having a groove formed therein; a metal protection layer disposed in the groove; a solder resist layer disposed on the insulation layer and having an opening exposing the circuit patterns; and a solder bump disposed in the opening.

The solder bump may include at least one of tin, lead, silver, or gold.

The metal protection layer may include at least one of nickel, gold, or alloys thereof.

The metal protection layer may not directly contact an outer upper surface of the solder resist layer.

According to another general aspect, a method of manufacturing a printed circuit board may include: preparing an insulation layer including circuit patterns disposed thereon; forming a groove by etching an outer upper surface of the circuit patterns; forming a solder resist layer on the insulation layer; forming an opening in the solder resist layer such that a surface of the groove is exposed; forming a metal protection layer by filling the groove; and forming a solder bump on the metal protection layer.

The etching of the outer upper surface of the circuit patterns may include laser drilling.

The forming of the opening may include forming the opening by exposure and development.

The solder bump may include at least one of tin, lead, silver, or gold.

The metal protection layer may include at least one of nickel, gold, or alloys thereof.

The metal protection layer may not directly contact an outer upper surface of the solder resist layer

According to another general aspect, a method of manufacturing a printed circuit board includes: preparing an insulation layer including circuit patterns disposed thereon; forming a solder resist layer on the insulation layer; forming an opening in the solder resist layer such that the circuit patterns are exposed to an external environment; forming a groove by etching an outer upper surface of the circuit patterns; forming a metal protection layer by filling the groove; and forming a solder bump on the metal protection layer.

The etching of the outer upper surface of the circuit patterns may include laser drilling.

The forming of the opening may include forming the opening by exposure and development.

The solder bump may include at least one of tin, lead, silver, or gold.

The metal protection layer may include at least one of nickel, gold, or alloys thereof.

The metal protection layer may not directly contact an outer upper surface of the solder resist layer.

Other features and aspects will be apparent from the following detailed description, the drawings, and the claims.

### BRIEF DESCRIPTION OF THE DRAWINGS

FIG. 1 is a cross-sectional view of a printed circuit board according to an example.

FIGS. 2 to 7 are cross-sectional views showing an example method of manufacturing the printed circuit board of FIG. 1.

FIGS. 8 to 13 cross-sectional views showing a method of manufacturing a printed circuit board according to another example.

Throughout the drawings and the detailed description, the same reference numerals refer to the same elements. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent to one of ordinary skill in the art. The sequences of operations described herein are merely examples, and are not limited to those set forth herein, but may be changed as will be apparent to one of ordinary skill in the art, with the exception of operations necessarily occurring in a certain order. Also, descriptions of functions and constructions that are well known to one of ordinary skill in the art may be omitted for increased clarity and conciseness.

The features described herein may be embodied in different forms, and are not to be construed as being limited to the examples described herein. Rather, the examples described herein have been provided so that this disclosure will be thorough and complete, and will convey the full scope of the disclosure to one of ordinary skill in the art.

Hereinafter, example embodiments will be described in detail with reference to the accompanying drawings.

Printed Circuit Board

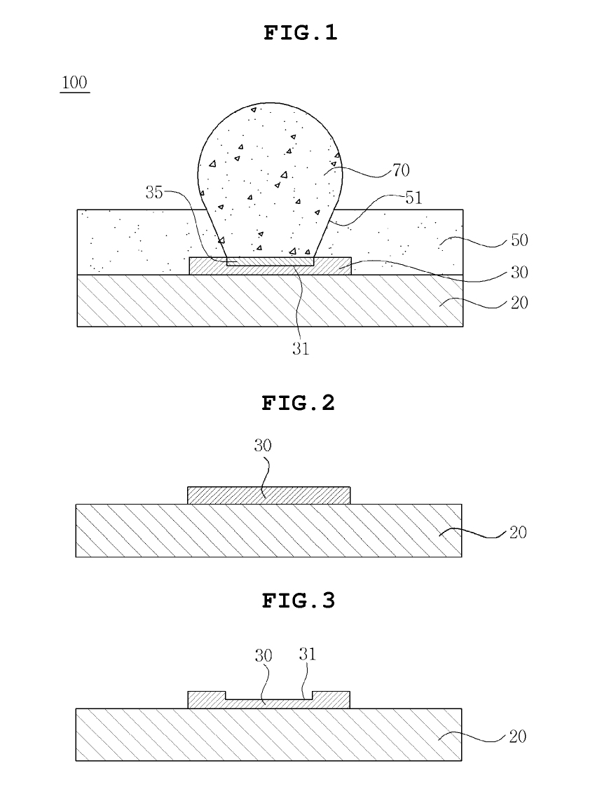

FIG. 1 is a cross-sectional view of a printed circuit board 100 according to an example.

Referring to FIG. 1, the printed circuit board 100 includes: an insulation layer 20 including circuit patterns 30 that are configured for electrical connection and have a groove 31 formed therein; a metal protection layer 35 formed by filling the groove 31; a solder resist layer 50 formed in the insulation layer 20 and having an opening 51 exposing the circuit patterns 30; and a solder bump 70 formed on the opening 51 of the solder resist layer 50.

In general, the insulation layer 20 is not limited to a specific composition as long as it is an insulation resin used as an insulation material in the printed circuit board 100. For example, a thermosetting resin such as an epoxy resin, a thermoplastic resin such as polyimide (PI), or a resin containing a reinforcing material such as a glass fiber or an inorganic filler impregnated therewith, for example, a prepreg, may be used as the insulation resin. In addition, a photo-curable resin that is capable of being cured by light, and the like, may be used. For example, the insulating layer 20 may be formed of a prepreg, Ajinomoto build-up film (ABF), FR-4, bismaleimide triazine (BT) resin, or the like.

The circuit patterns 30 are formed on the insulation layer 20 and may be formed of at least one electroconductive metal selected from gold (Au), silver (Ag), copper (Cu), and nickel (Ni). However, the circuit patterns 30 are not limited to the foregoing materials.

The circuit patterns 30 have a step due to the groove 31 formed therein, and the metal protection layer 35 is formed in the groove 31. The metal protection layer 35 is also referred to as under bump metallurgy (UBM), and may include at least one metal selected from nickel (Ni), gold (Au), and alloys thereof. The metal protection layer 35 is configured to protect the circuit patterns 30 from external damage such as scratches, corrosion, wettability, and the like. In addition, the metal protection layer 35 may be formed by filling the groove 31 in the circuit patterns 30 to increase a bonding force.

The opening 51 in the solder resist layer 50 may have the same width as a width of the groove 31 in the circuit patterns 30. Accordingly, the surface of the metal protection layer 35 may be exposed at a surface of the circuit patterns 30 within the opening 51. A width of the groove 31 may match the width of the opening 51.

Since the metal protection layer 35 is formed by filling the groove 31, the metal protection layer 35 does not directly contact an outer upper surface of the solder resist layer 50.

The related art has a problem in that since the metal protection layer is formed on the circuit patterns, the metal protection layer directly contacts the surface of the solder resist layer to be stacked later, such that voids or cracks occur, which causes defects.

However, in the printed circuit board 100, the metal protection layer 35 is embedded in the circuit patterns 30, such that the metal protection layer 35 does not directly contact a surface (e.g., the outer upper surface) of the solder resist layer 50 which is to be stacked later. In other words, an interface is not formed directly between the metal protection layer 35 and a surface of the solder resist layer 50 to be stacked later. Accordingly, when the solder bump 70 is formed on the metal protection layer 35, defects such as voids or cracks that may occur at an interface on the outer upper surface of the solder resist layer 50 may be prevented.

The solder bump 70 is formed on an externally exposed surface of the metal protection layer 35 through the opening 51 in the solder resist layer 50. The solder bump 70 protrudes from an inner side of the solder resist layer 50 toward the outer upper surface of the solder resist layer 50, and is generally formed to have a spherical shape, but is not limited thereto.

The solder bump 70 may include at least one metal selected from tin (Sn), lead (Pb), silver (Ag), or gold (Au), but is not limited thereto.

Manufacturing Method of Printed Circuit Board

FIGS. 2 to 7 are cross-sectional views showing an example method of manufacturing the printed circuit board 100.

The method of manufacturing the printed circuit board 100 includes: preparing the insulation layer 20 including the circuit patterns 30 formed thereon; forming the groove 31 by etching an outer upper surface of the circuit patterns 30; forming the solder resist layer 50 on the insulation layer 20; forming the opening 51 in the solder resist layer 50 so that a surface of the groove 31 formed on the circuit patterns 30 is exposed; forming the metal protection layer (under bump metallurgy (UBM)) 35 by filling the groove 31; and forming the solder bump 70 on the metal protection layer 35.

In general, the insulation layer 20 is not limited to a specific composition as long as it is an insulation resin used as an insulation material in the printed circuit board 100. For example, a thermosetting resin such as an epoxy resin, a thermoplastic resin such as polyimide (PI), or a resin containing a reinforcing material such as a glass fiber or an inorganic filler impregnated therewith, for example, a prepreg, may be used as the insulation resin. In addition, a photo-curable resin that is capable of being cured by light, and the like, may be used. For example, the insulating layer 20 may be formed of a prepreg, Ajinomoto build-up film (ABF), FR-4, bismaleimide triazine (BT) resin, or the like.

Referring to FIG. 2, the circuit patterns 30 are formed on the insulation layer 20 and may be formed of at least one electroconductive metal selected from gold (Au), silver (Ag), copper (Cu), or nickel (Ni). The circuit patterns 30 are not, however, limited to the aforementioned metals.

Referring to FIG. 3, the groove 31 may be formed by etching an outer upper surface of the circuit patterns 30 by a laser drilling method, such as CO2 or YAG laser drilling, but is not specifically limited to being formed by such a method.

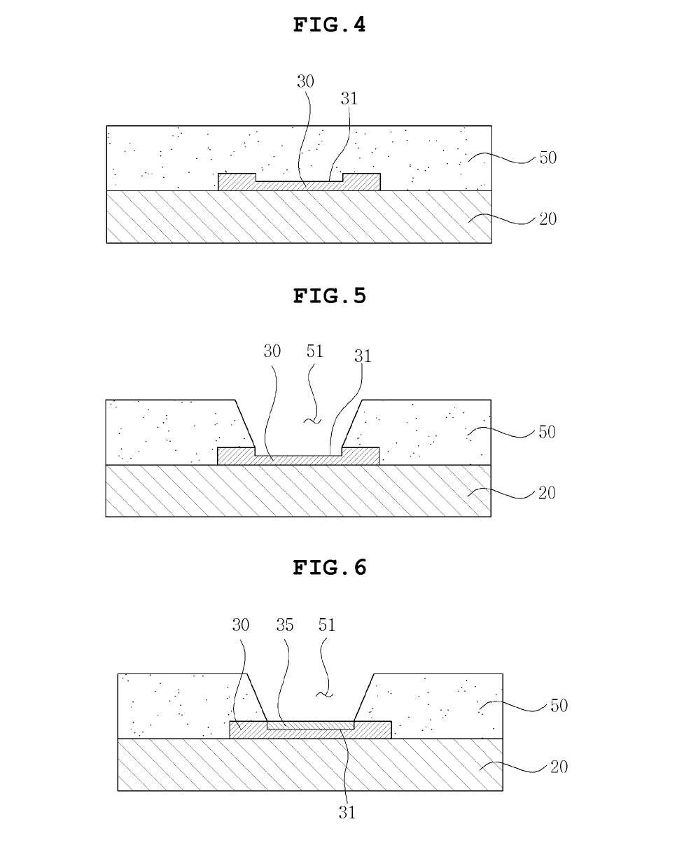

Referring to FIG. 4, the solder resist layer 50 may be formed on the insulation layer 20 by coating a liquid phase solder resist composition or stacking a film-type solder resist. However, the solder resist layer 50 may be formed by any method known in the art.

Referring to FIG. 5, the opening 51 in the solder resist layer 50 may be formed so that a surface of the groove 31 is exposed to the external environment. In addition, the opening 51 may be formed by exposure and development.

A width of the groove of 31 may be formed to match a width of the opening 51.

The metal protection layer 35 (under bump metallurgy (UBM)) is formed in the groove 31. The metal protection layer 35 may include at least one metal selected from nickel (Ni), gold (Au), and alloys thereof. The metal protection layer 35 is configured to protect the circuit patterns 30 from external damage such as scratches, corrosion, wettability, and the like.

Referring to FIG. 6, the metal protection layer 35 is formed by a process such as a sputtering method or electroless plating, but is not limited to being formed by these specific processes. Accordingly, interlayer adhesion between the circuit patterns 30 and the metal protection layer 35 may be increased.

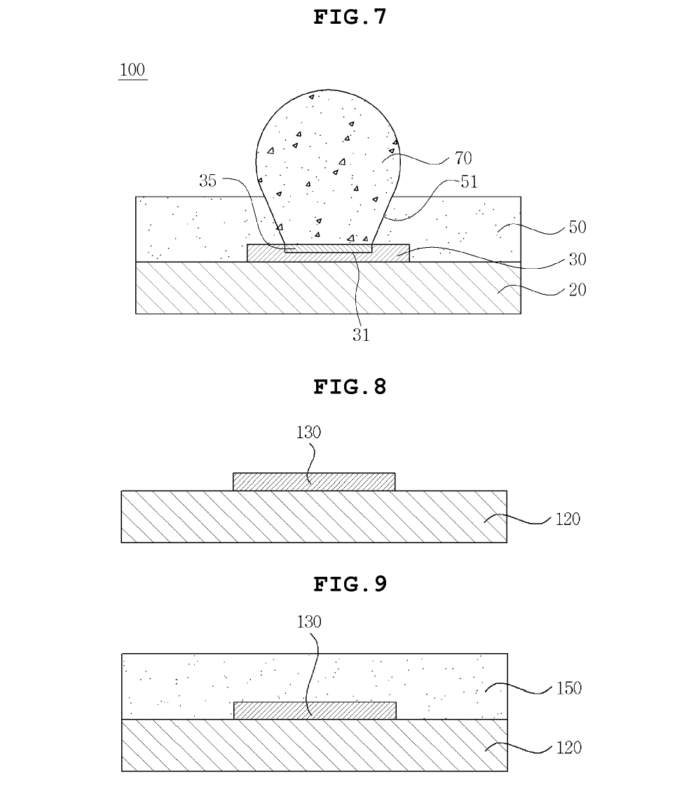

Referring to FIG. 7, the solder bump 70 is formed on the metal protection layer 35. The solder bump 70 may be formed by a reflow process, but is not specifically limited to being formed by such a process. Further, the solder bump 70 may include at least one metal selected from tin (Sn), lead (Pb), silver (Ag), or gold (Au), and may further include a conductive polymer.

In the method of manufacturing the printed circuit board 100, the metal protection layer 35 is embedded in the circuit patterns 30, such that an interface is not formed directly between the metal protection layer 35 and a surface (e.g., outer upper surface) of the solder resist layer 50 to be stacked later. Accordingly, when the solder bump 70 is formed on the metal protection layer 35, defects such as voids or cracks that may occur at an interface on an outer upper surface of the solder resist layer 50 may be prevented.

FIGS. 8 to 13 are cross-sectional views showing a method of manufacturing a printed circuit board 200 according to another example.

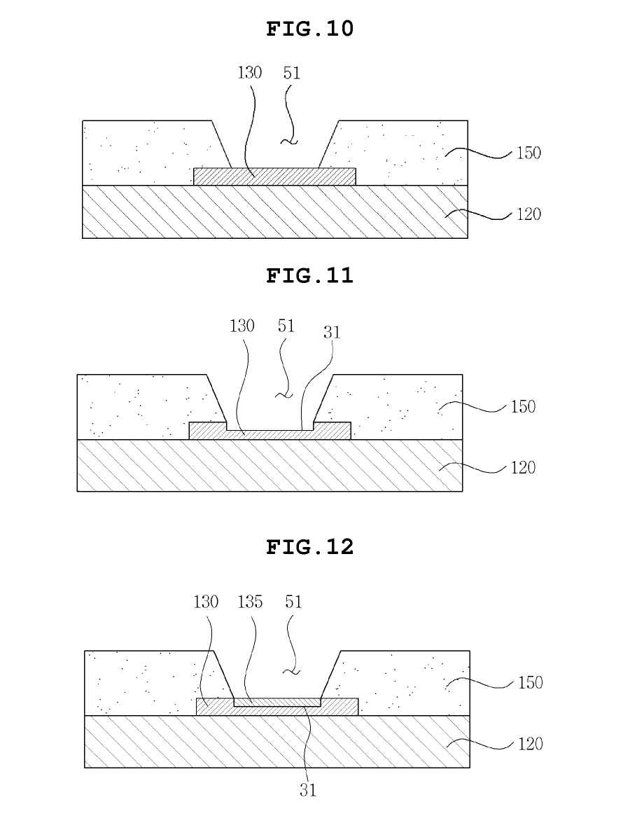

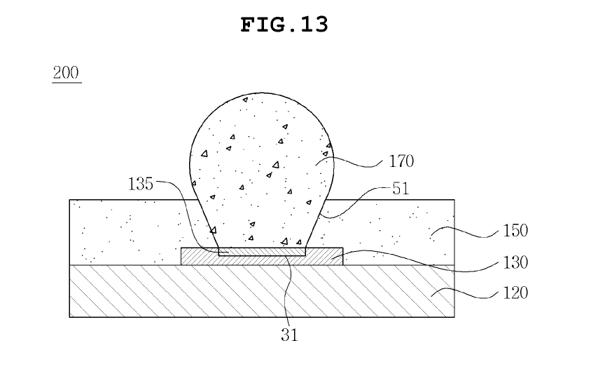

Referring to FIGS. 8 to 13, the method of manufacturing the printed circuit board 200 includes: preparing an insulation layer 120 including circuit patterns 130 formed thereon (FIG. 8); forming a solder resist layer 150 on the insulation layer 120 (FIG. 9); forming an opening 51 in the solder resist layer 150 so that the circuit patterns 130 are exposed to the external environment (FIG. 10); forming a groove 31 (FIG. 11) by etching an outer upper surface of the circuit patterns 130; forming a metal protection layer (under bump metallurgy (UBM)) 135 by filling the groove 31 (FIG. 12); and forming a solder bump 170 on the metal protection layer 135 (FIG. 13).

In the method of manufacturing the printed circuit board 200, unlike the manufacturing method of the printed circuit board 100, the solder resist layer 150 is formed before the groove 31 is formed, the opening 51 of the solder resist layer 150 is subsequently formed so that the circuit patterns 130 are exposed to the external environment through the opening 51, and an upper surface of the circuit patterns 130 exposed to the external environment is then etched to form the groove. Accordingly, the printed circuit boards 100 and 200 differ with respect to the process sequence of their manufacturing methods, but have substantially the same final structure.

Even in the manufacturing method of the printed circuit board 200, the metal protection layer 135 is embedded in the circuit patterns 130, such that an interface is not formed directly between the metal protection layer 135 and an outer upper surface of the solder resist layer 150 to be stacked later. Accordingly, when the solder bump 170 is formed on the metal protection layer 135, defects such as voids or cracks that may occur at an interface on the outer upper surface of the solder resist layer 150 may be prevented.

In the method of manufacturing the printed circuit board 200, the specific description and applied processes of the insulation layer 120, the circuit patterns 130, the metal protection layer 135, and the solder bump 170 are the same as the above description of the method of manufacturing the printed circuit board 100, and the overlapping description is therefore omitted with respect to the printed circuit board 200.

While this disclosure includes specific examples, it will be apparent to one of ordinary skill in the art that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents. Therefore, the scope of the disclosure is defined not by the detailed description, but by the claims and their equivalents, and all variations within the scope of the claims and their equivalents are to be construed as being included in the disclosure.

What is claimed is:

1. A printed circuit board comprising:
an insulation layer comprising circuit patterns, the circuit patterns having a groove formed therein;
a metal protection layer disposed in the groove;
a solder resist layer disposed on the insulation layer and comprising an opening exposing the circuit patterns; and
a solder bump disposed in the opening.

2. The printed circuit board of claim 1, wherein the solder bump comprises at least one of tin, lead, silver, or gold.

3. The printed circuit board of claim 1, wherein the metal protection layer comprises at least one of nickel, gold, or alloys thereof.

4. The printed circuit board of claim 1, wherein the metal protection layer does not directly contact an outer upper surface of the solder resist layer.

5. A method of manufacturing a printed circuit board, the method comprising:
preparing an insulation layer comprisng circuit patterns disposed thereon;
forming a groove by etching an outer upper surface of the circuit patterns;
forming a solder resist layer on the insulation layer;
forming an opening of the solder resist layer so that a surface of the groove is exposed;
forming a metal protection layer by filling the groove; and
forming a solder bump on the metal protection layer.

6. The method of claim 5, wherein the etching of the outer upper surface of the circuit patterns comprises laser drilling.

7. The method of claim 5, wherein the forming of the opening comprises forming the opening by exposure and development.

8. The method of claim 5, wherein the solder bump comprises at least one of tin, lead, silver, or gold.

9. The method of claim 5, wherein the metal protection layer comprises at least one of nickel, gold, or alloys thereof.

10. The method of claim 5, wherein the metal protection layer does not directly contact an outer upper surface of the solder resist layer.

11. A method of manufacturing a printed circuit board, the method comprising:
preparing an insulation layer including circuit patterns disposed thereon;
forming a solder resist layer on the insulation layer;
forming an opening in the solder resist layer such that the circuit patterns are exposed to an external environment through the opening;
forming a groove by etching an outer upper surface of the circuit patterns;
forming a metal protection layer by filling the groove; and
forming a solder bump on the metal protection layer.

12. The method of claim 11, wherein the etching of the outer upper surface of the circuit patterns comprises laser drilling.

13. The method of claim 11, wherein the forming of the opening comprises forming the opening by exposure and development.

14. The method of claim 11, wherein the solder bump comprises at least one of tin, lead, silver, or gold.

15. The method of claim 11, wherein the metal protection layer comprises at least one of nickel, gold, or alloys thereof.

16. The method of claim 11, wherein the metal protection layer does not directly contact an outer upper surface of the solder resist layer.
